(19) United States
(12) Patent Application Publication
(10) Pub. No.: US 2023/0308028 A1
(43) Pub. Date: Sep. 28, 2023

(54) DC-AC CONVERTER, AND AC OUTPUT DEVICE

(71) Applicant: SHANGHAI RUNHOOD POWER CO., LTD., SHANGHAI (CN)

(72) Inventors: XIAODONG WANG, SHANGHAI (CN); ZHONGSHU CHEN, SHANGHAI (CN); WEI QIN, SHANGHAI (CN)

(21) Appl. No.: 18/054,549

(22) Filed: Nov. 11, 2022

(30) Foreign Application Priority Data
Mar. 28, 2022 (CN) 202220736970.8

(51) Int. Cl. H02M 7/00; H02J 9/06; H01R 13/66; H02J 7/02; H02J 7/00

(52) U.S. Cl. CPC H02M 7/003; H02J 9/061; H01R 13/6675; H02J 7/02; H02J 7/0045

(57) ABSTRACT

Embodiments of the present disclosure provide a DC-AC converter, including: a converter housing; an electrical connector, arranged on the converter housing and configured to be electrically connected with the battery module; a DC-AC conversion module arranged in the converter housing and configured to convert a direct current output from the battery module to an alternating current; and a detachable connection structure arranged on the converter housing and configured to detachably connect the DC-AC converter to the battery module. Embodiments of the present disclosure further provide an AC output device, in which the DC-AC converter is detachably connected to the battery module. The DC-AC converter can be detached from the AC output device when the user does not need the current conversion function.

### CROSS REFERENCE TO RELATED APPLICATIONS

The present application claims the benefit of priority under the Paris Convention to Chinese Patent Application No. 202220736970.8 filed on Mar. 28, 2022, which is incorporated herein by reference in its entirety.

### TECHNICAL FIELD

Embodiments of the present disclosure relate to the field of portable power source technology, and in particular to a direct current to alternating current (DC-AC) converter, and an AC output device.

### BACKGROUND

The portable power sources meet people's requirements for electricity in outdoor activities, and offer conveniences to users in some emergency situations. With an increasing energy storage level, the portable power sources are more and more favored by consumers.

The existing portable power sources conventionally each have a current conversion module arranged inside the portable power source and configured to convert currents. The current conversion module usually leads to a large size and inconvenience in carrying of the portable power source and a poor user experience, due to the current conversion module, together with batteries, being integrally and fixedly disposed in the portable power source. In particular, in a case that a user does not need the current conversion function, the built-in current conversion module would be cumbrous to the user.

### SUMMARY

Embodiments of the present disclosure aim to provide a DC-AC converter and an AC output device. The DC-AC converter can be detachably connected with a battery module, and can be detached from the AC output device when the user does not need the current conversion function. In this way, a size of the AC output device can be reduced, and portability and user experience of the AC output device can be improved.

To this end, some embodiments of the present disclosure provide a DC-AC converter, configured to be connected with a battery module and including:
a converter housing; an electrical connector, arranged on the converter housing and configured to be connected with the battery module; a DC-AC conversion module arranged in the converter housing and configured to convert a direct current output from the battery module to an alternating current; and a detachable connection structure arranged on the converter housing and configured to be detachably connected with the battery module.

Some embodiments of the present disclosure further provide an AC output device, including: a battery module; and the above-mentioned DC-AC converter; the battery module is detachably connected to the DC-AC converter, and the battery module is electrically connected to the DC-AC conversion module.

The DC-AC converter according to the present disclosure includes a converter housing, an electrical connector arranged on the converter housing, a DC-AC conversion module arranged in the converter housing and a detachable connection structure arranged on the converter housing. The electrical connector is configured to be connected with the battery module. The DC-AC conversion module is configured to convert a direct current output from the battery module to an alternating current. The detachable connection structure is configured to detachably connect the DC-AC converter to the battery module. Compared with the converter in the related art, the DC-AC converter according to the present disclosure can be detachably connected with the battery module, and can be detached from the AC output device when the user does not need the current conversion function. In this way, a size of the AC output device can be reduced, and portability and user experience of the AC output device can be improved.

In some examples, the DC-AC converter includes at least two detachable connection structures arranged on the converter housing, and the at least two detachable connection structures are spaced from each other. At least two first through-holes are defined on the converter housing, the at least two detachable connection structures and the at least two first through-holes are in one-to-one correspondence, and a respective detachable connection structure passes through a corresponding first through-hole. The at least two detachable connection structures can provide a secure connection between the DC-AC converter and the battery module. The at least two first through-holes to be passed through by the detachable connection structures can be used to reduce the size of the DC-AC converter by arranging the detachable connection structures inside the converter housing.

In some examples, each of the at least two detachable connection structures includes a clasp member configured to fasten with a groove defined on the battery module. With the detachable connection structure designed as the clasp member configured to fasten with the groove of the battery module, the construction of the detachable connection structure can be simplified, and the production complexity of the DC-AC converter can be reduced.

In some examples, the clasp member includes a resilient part having two ends opposite to each other, a hook, and a controlling button. One end of the resilient part is fixed to an inner wall of the converter housing, and the other end of the resilient part is connected to the hook. The hook passes through a corresponding first through-hole to extend from inside to outside of the converter housing. A second through-hole is defined on the converter housing, and the controlling button is inserted in the second through-hole and connected with the hook. The at least two first through-holes are defined on a first face of the converter housing, and the second through-hole is defined on a second face of the converter housing different from the first face. The hook is configured to fasten with the battery module. The controlling button is configured to drive the hook to compress the resilient part. When detaching the DC-AC converter from the battery module, the controlling button is pressed to drive the hook to compress the resilient part, such that the hook is unfastened with the battery module. In this way, a fast detachment of the DC-AC converter can be achieved. Then the controlling button is released, such that the resilient part pushes on the hook to return the hook to its original position. In this way, the detachment operation of the DC-AC converter can be simplified, and the user experience can be improved.

In some examples, a third through-hole is defined on the converter housing, the electrical connector passes through the third through-hole to extend to outside of the converter housing, and the third through-hole and the at least two first through-holes are defined on a same face of the converter housing. The electrical connector and the detachable connection structures are arranged at a same face of the converter housing, in this way, during the connection of DC-AC converter to the battery module via the detachable connection structures, the electrical connection between the electrical connector and the battery module and the connection between the detachable connection structures and the battery module are performed on a same face of the converter housing, such that the operation can be simplified, and the user experience can be improved.

In some examples, the DC-AC converter further includes a front panel and an output socket. The front panel is fixed to the converter housing and forms a receiving space with the converter housing, and the DC-AC conversion module is received in the receiving space. A fourth through-hole is defined on the front panel, and the output socket passes through the fourth through-hole to extend from the receiving space to outside of the converter housing. The DC-AC conversion module is received in the receiving space formed by the front panel and the converter housing, in this way, internal elements including the DC-AC conversion module can be protected by the front panel and the converter housing.

In some examples, the DC-AC converter further includes a fan and a circuit board. The fan is received in the receiving space and fixed to the front panel. The circuit board is received in the receiving space and electrically connected to the fan. A heat emission hole is defined on a side wall of the converter housing adjacent to a side wall of the converter housing at which the electrical connector is arranged. The fan arranged in the DC-AC converter can twirl and generate an airflow to take away the heat generated by the DC-AC conversion module during the current conversion operation of the DC-AC converter upon being connected with the battery module. In this way, the DC-AC converter can be kept in stable operation.

In some examples, the DC-AC converter further includes a fan bracket received in the receiving space and fixed to the front panel, and the fan is fixed on the fan bracket. In this way, the fan can be suspended to increase the spacing between internal elements, such that the heat dissipation efficiency can be improved.

In some examples, a groove is defined on the battery module, and the groove is detachably fastened with the detachable connection structure of the DC-AC converter. In this way, an alternating current can be obtained by simply attaching the DC-AC converter with the battery module, such that operations can be simplified.

### BRIEF DESCRIPTION OF THE DRAWINGS

FIG. 1 is a structural schematic diagram of the DC-AC converter according to some embodiments of the present disclosure.

FIG. 2 is a schematic diagram of the detachable connection structure of the DC-AC converter according to some embodiments of the present disclosure.

FIG. 3 is a structural schematic diagram of the clasp member of the DC-AC converter according to some embodiments of the present disclosure.

FIG. 4 is a schematic diagram of the electrical connector of the DC-AC converter according to some embodiments of the present disclosure.

FIG. 5 is an explosive view of the structure of the DC-AC converter according to some embodiments of the present disclosure.

FIG. 6 is a structural schematic diagram of the AC output device according to some embodiments of the present disclosure.

FIG. 7 shows another type of the output socket of the DC-AC converter according to some embodiments of the present disclosure.

### DETAILED DESCRIPTION OF THE EMBODIMENTS

In order to make the purposes, technical solutions and advantages of the embodiments of the present disclosure more clear, the embodiments of the present disclosure will be described in detail below in reference to the accompanying drawings. Those skilled in the art should understand that in the embodiments of the present disclosure, many technical details are proposed to enable readers to better understand the present disclosure. However, even without these technical details and various changes and modifications based on the following embodiments, the technical solution claimed in the present disclosure can be realized.

In the embodiments of the present disclosure, the terms such as “up”, “down”, “left”, “right”, “front”, “rear”, “top”, “bottom”, “inside”, “outside”, “middle”, “vertical”, “horizontal”, “transverse”, “longitudinal” or the like those indicate orientation or position relationships are based on the orientation or position relationships as shown in the drawings. These terms are mainly used to better describe the present disclosure and its embodiments, but not to define that the corresponding device, element or component must have a specific orientation, or be constructed and operated in a specific orientation.

In addition, some of the above terms can have other meanings besides the orientation or position relationships. For example, the term “up” may also be used to define an attachment or connection relationship in some cases. For those skilled in the art, the specific meanings of these terms in the present disclosure should be interpreted according to specific situations.

Moreover, the terms such as “installation”, “arrangement”, “providing with”, “opening”, “connection” and “inter-connection” should be interpreted broadly. For example, it may be a fixed connection, a detachable connection, or an integral structure; or it may be a mechanical connection or an electrical connection; or it may be a direct connection, or an indirect connection via an intermediate media, or an internal communication between two devices, elements or components. For those skilled in the art, the specific meanings of these terms in the present disclosure should be interpreted according to specific situations.

Furthermore, the terms “first”, “second” or the like are mainly used to distinguish different devices, elements or components (of the same or different types and structures), but not to indicate or imply the relative importance and quantity of the corresponding devices, elements or components. Unless otherwise specified, “a plurality of” means two or more.

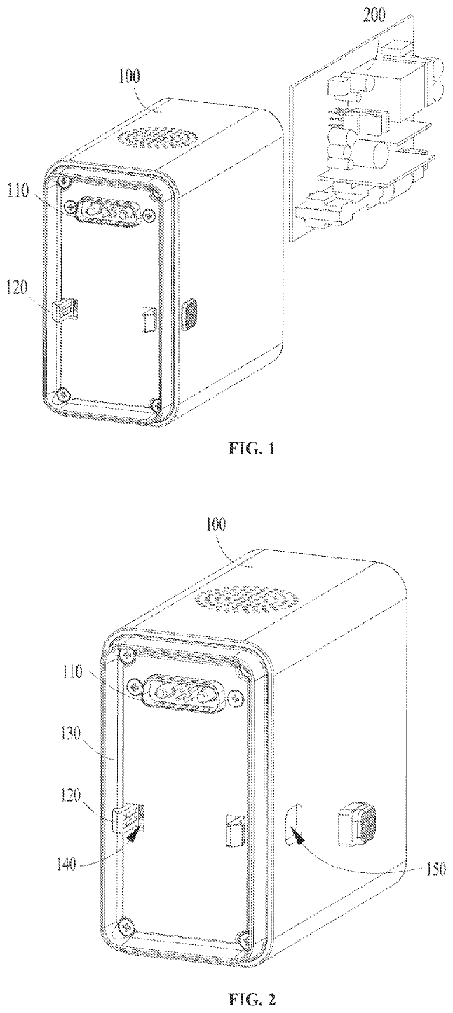

Some embodiments of the present disclosure provide a DC-AC converter, as shown in FIG. 1, including a converter housing 100; and an electrical connector 110 arranged on the converter housing 100 and configured to be connected with the battery module. The DC-AC converter further includes a DC-AC conversion module 200 arranged in the converter housing 100 and configured to convert a direct current output from the battery module to an alternating current. The DC-AC converter further includes a detachable connection structure 120 arranged on the converter housing 100 and configured to be detachably connected with the battery module.

The DC-AC converter according to some embodiments of the present disclosure includes a converter housing 100, an electrical connector 110 arranged on the converter housing 100, a DC-AC conversion module 200 arranged in the converter housing 100 and a detachable connection structure 120 arranged on the converter housing 100. The electrical connector 110 is configured to be electrically connected with the battery module. The DC-AC conversion module 200 is configured to convert a direct current output from the battery module to an alternating current. The detachable connection structure 120 is configured to detachably connect the DC-AC converter to the battery module. Compared with the converter in the related art, the DC-AC converter according to the present disclosure can be detachably connected with the battery module, and can be detached from the AC output device when the user does not need the current conversion function. In this way, a size of the AC output device can be reduced, and portability and user experience of the AC output device can be improved.

In some embodiments, the converter housing 100 may be made of plastic, aluminum alloy or other materials, as long as the obtained converter housing 100 has enough strength and waterproof and heat-resistant properties to a certain extent, so that the DC-AC converter can work normally. The embodiments of the present disclosure are not limited to this.

Reference is further made to FIG. 2, in some embodiments, a positioning projection 130 is arranged at an edge of respective side wall of a lateral sheet of the converter housing 100 on which the detachable connection structure is arranged. With the positioning projection 130, the DC-AC converter can be positioned quickly and accurately when the DC-AC converter is detachably connected to the battery module. In this way, the installation efficiency of the DC-AC converter can be improved.

In some embodiments, the positioning projection 130 may be an integrated projection arranged surrounding the edges of side walls of the lateral sheet of the converter housing 100, or the positioning projections 130 may be multiple segmented projections arranged at intervals surrounding the edges. In some other embodiments, the positioning projections 130 may be multiple positioning structures arranged at intervals on the side walls of the lateral sheet of the converter housing 100, as long as the DC-AC converter can be accurately positioned and quickly installed during the installation of the DC-AC converter. The embodiments of the present disclosure are not limited to this.

Reference is further made to FIG. 2, in some embodiments, the DC-AC converter includes at least two detachable connection structures 120 arranged on the converter housing 100, and the at least two detachable connection structures 120 are spaced from each other. At least two first through-holes 140 are defined on the converter housing 100, the at least two detachable connection structures 120 and the at least two first through-holes 140 are in one-to-one correspondence, and a respective detachable connection structure 120 passes through a corresponding first through-hole 140. The at least two detachable connection structures 120 can provide a secure connection between the DC-AC converter and the battery module. The at least two first through-holes 140 to be passed through by the detachable connection structures 120 can be used to reduce the size of the DC-AC converter by arranging the detachable connection structures 120 inside the converter housing 100.

In some embodiments, each of the at least two detachable connection structures 120 includes a clasp member configured to fasten with a groove defined on the battery module. With the detachable connection structure 120 designed as the clasp member configured to fasten with the groove of the battery module, the construction of the detachable connection structure 120 can be simplified, and the production complexity of the DC-AC converter can be reduced.

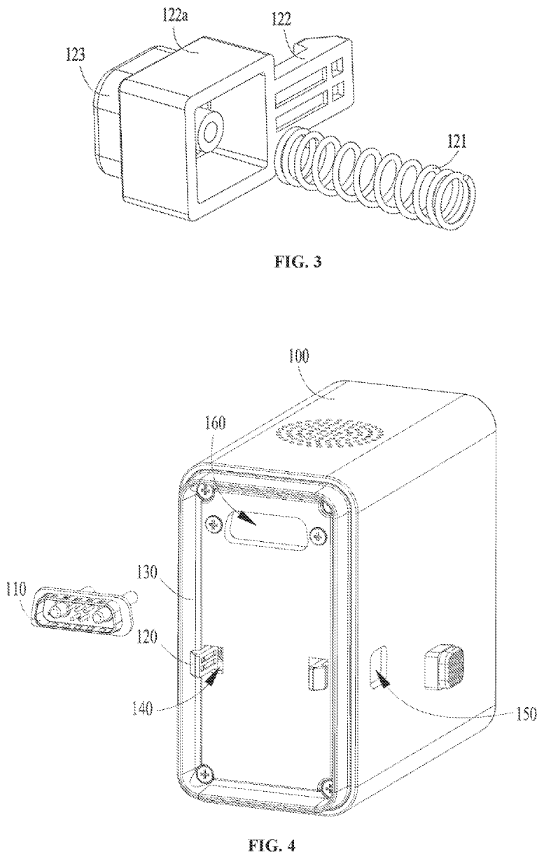

Reference is made to FIG. 3, in some embodiments, the clasp member includes a resilient part 121 having two ends opposite to each other, a hook 122, and a controlling button 123. One end of the resilient part is fixed to an inner wall of the converter housing 100, and the other end of the resilient part is connected to the hook 122. The hook 122 passes through a corresponding first through-hole 140 to extend from inside to outside of the converter housing 100. The hook 122 is configured to fasten with the battery module. A second through-hole 150 is defined on the converter housing 100, and the controlling button 123 is inserted in the second through-hole 150 and connected with the hook 122. The at least two first through-holes 140 are defined on a first face of the converter housing 100, and the second through-hole 150 is defined on a second face of the converter housing 100 different from the first face. The controlling button 123 is configured to drive the hook 122 to compress the resilient part 121. When detaching the DC-AC converter from the battery module, the controlling button 123 is pressed to drive the hook 122 to compress the resilient part 121, such that the hook 122 is unfastened with the battery module. In this way, a fast detachment of the DC-AC converter can be achieved. Then the controlling button 123 is released, such that the resilient part 121 pushes on the hook 122 to return the hook 122 to its original position. In this way, the detachment operation of the DC-AC converter can be simplified, and the user experience can be improved.

Reference is further made to FIG. 3, in some embodiments, the hook 122 includes a limiting convex part 122a being in contact with the inner wall of the converter housing 100. The limiting convex part 122a is used to limit the hook 122, in order to prevent the hook 122 from detaching from the converter housing 100. In this way, the integrity of the DC-AC converter can be ensured.

In some embodiments, the resilient part 121 may be an elastic part, such as a spring, silica gel, foam or the like, as long as it can elastically deform under the pressure of the hook 122, and can restore without the action of the hook 122 and return the hook to its original position. Embodiments of the present disclosure are not limited to this.

It should be understood that, the detachable connection structure 120 also may include an interlocking structure or a detachable connection structure of other types, as long as it can implement the quick connection and detachment between the DC-AC converter and the battery module, embodiments of the present disclosure are not limited to this.

Reference is made to FIG. 4, in some embodiments, a third through-hole 160 is defined on the converter housing 100, the electrical connector 110 passes through the third through-hole 160 to extend to outside of the converter housing 100, and the third through-hole 160 and the at least two first through-holes 140 are defined on a same face of the converter housing 100. The electrical connector 110 and the detachable connection structures 120 are arranged at a same face of the converter housing 100, in this way, during the connection of DC-AC converter to the battery module via the detachable connection structures 120, the electrical connection between the electrical connector 110 and the battery module and the connection between the detachable connection structures 120 and the battery module are performed on a same face of the converter housing, such that the operation can be simplified, and the user experience can be improved.

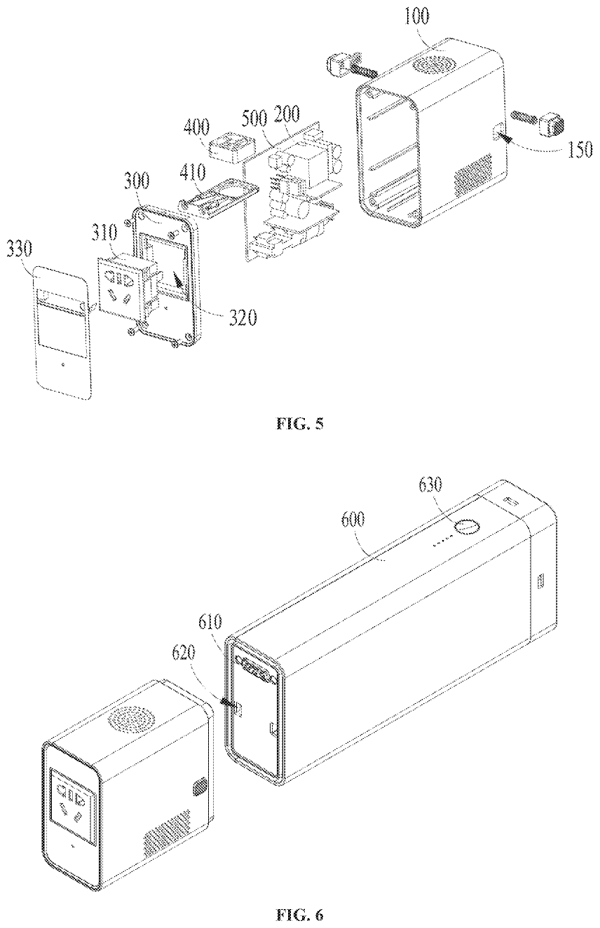

Reference is made to FIG. 5, in some embodiments, the DC-AC converter further includes a front panel 300 and an output socket 310. The front panel 300 is fixed to the converter housing 100 and forms a receiving space with the converter housing 100, and the DC-AC conversion module 200 is received in the receiving space. A fourth through-hole 320 is defined on the front panel 300, and the output socket 310 passes through the fourth through-hole 320 to extend from the receiving space to outside of the converter housing 100. The DC-AC conversion module 200 is received in the receiving space formed by the front panel 300 and the converter housing 100, in this way, internal elements including the DC-AC conversion module 200 can be protected by the front panel 300 and the converter housing 100.

It should be understood that the shapes and sizes of the front panel 300 and the output socket 310 can be adjusted according to actual requirements, as long as when connecting the DC-AC converter to the battery module, the electrical equipment can obtain electrical energy by being connected with the output socket 310, embodiments of the present disclosure are not limited to this.

In some embodiments, a surface of the front panel 300 away from the receiving space is further provided with a decorative sticker 330. The decorative sticker 300 is used to cover the connector that fixedly connects the front panel 300 and the converter housing 100. In this way, the connector can be protected and the service life of the connector can be increased.

Reference is made to FIG. 5 again, in some embodiments, the DC-AC converter further includes a fan 400 and a circuit board 500. The fan 400 is received in the receiving space and fixed to the front panel 300. The circuit board 500 is received in the receiving space and electrically connected to the fan 400. A heat emission hole is defined on a side wall of the converter housing 100 adjacent to a side wall of the converter housing 100 at which the electrical connector 110 is arranged. The fan 400 arranged in the DC-AC converter can twirl and generate an airflow to take away the heat generated by the DC-AC conversion module 200 during the current conversion operation of the DC-AC converter upon being connected with the battery module. In this way, the DC-AC converter can be kept in stable operation.

In some examples, the DC-AC converter further includes a fan bracket 410 received in the receiving space and fixed to the front panel 300, and the fan 400 is fixed on the fan bracket 410. In this way, the fan 400 can be suspended to increase the spacing between internal elements, such that the heat dissipation efficiency can be improved.

It should be understood that the connection modes between the components of the DC-AC converter may include screw connection, snap-fit, gluing, riveting or other connection modes, as long as the components can be firmly combined and the DC-AC converter can function normally. The embodiments of the present disclosure are not limited to this.

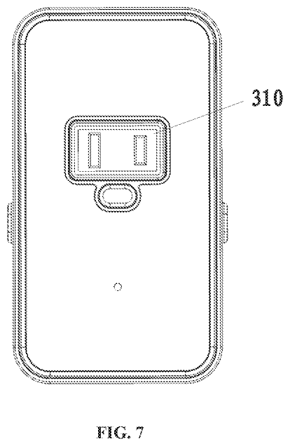

Some embodiments of the present disclosure provide an AC output device. Reference is made to FIG. 6, the AC output device includes a battery module 600 and the above-mentioned DC-AC converter. The battery module 600 is detachably connected with the DC-AC converter, and is electrically connected with the DC-AC conversion module 200.

The AC output device according to the present disclosure includes a battery module 600 and the above-mentioned DC-AC converter. The battery module 600 is detachably connected with the DC-AC converter, and is electrically connected with the DC-AC conversion module 200. Compared with the AC output device in the related art, the battery module 600 and the DC-AC conversion module of the AC output device according to the present disclosure are combined as one piece when the battery module 600 is connected with the DC-AC conversion module. In this way, the AC output device has high connection strength and stability, and is convenient to carry. When the power consumption ends, the DC-AC converter can be detached. In this way, the size of the AC output device can be reduced.

Reference is made to FIG. 6 again, in some embodiments, the battery module 600 is provided with a connector assembly 610 via which the battery module 600 is electrically connected to the DC-AC converter. The connector assembly 610 supports hot plugging. In this way, users can replace the battery module at any time as needed.

In some embodiments, a groove 620 is defined on the battery module 600, and the groove 620 is configured to be detachably fastened with the DC-AC converter. In this way, an alternating current can be obtained by simply attaching the DC-AC converter with the battery module, such that operations can be simplified.

In some other embodiments, the detachable connection structure 120 may be arranged on the battery module 600, and the groove 620 may be defined on the DC-AC converter.

In some embodiments, the battery module 600 is further provided with a button 630 by which the battery module 600 is started up or shut off. With the button 630 configured for controlling the operation state of the battery module 600, the safety performance of the battery module 600 can be improved.

In some embodiments, the output socket 310 of the DC-AC converter also can be implemented in another form as shown in FIG. 7.

The above describes the DC-AC converter and AC output device provided by the embodiments of the present disclosure in detail. Herein, examples are used to illustrate the principle and implementations of the invention. The above description of the embodiments is only used to help understand the idea of the present disclosure, and there will be changes in the implementations and application scope. In conclusion, the content of this description should not be interpreted as a limitation on the scope of protection of the present disclosure.

What is claimed is:

1. A direct current to alternating current (DC-AC) converter, configured to be connected with a battery module and comprising:
a converter housing;
an electrical connector, arranged on the converter housing and configured to be connected with the battery module;
a DC-AC conversion module, arranged in the converter housing and configured to convert a direct current output from the battery module to an alternating current; and
a detachable connection structure, arranged on the converter housing and configured to be detachably connected with the battery module.

2. The DC-AC converter according to claim 1, comprising at least two detachable connection structures arranged on the converter housing, wherein the at least two detachable connection structures are spaced from each other; and
at least two first through-holes are defined on the converter housing, wherein the at least two detachable connection structures and the at least two first through-holes are in one-to-one correspondence, and a respective detachable connection structure passes through a corresponding first through-hole.

3. The DC-AC converter according to claim 2, wherein each of the at least two detachable connection structures comprises a clasp member configured to fasten with a groove defined on the battery module.

4. The DC-AC converter according to claim 3, wherein the clasp member comprises a resilient part having two ends opposite to each other, a hook, and a controlling button, wherein one end of the resilient part is fixed to an inner wall of the converter housing, the other end of the resilient part is connected to the hook, and the hook passes through a corresponding first through-hole to extend from inside to outside of the converter housing;
a second through-hole is defined on the converter housing, wherein the controlling button is inserted in the second through-hole and connected with the hook, the at least two first through-holes are defined on a first face of the converter housing, and the second through-hole is defined on a second face of the converter housing different from the first face.

5. The DC-AC converter according to claim 2, wherein a third through-hole is defined on the converter housing, the electrical connector passes through the third through-hole to extend to outside of the converter housing, and the third through-hole and the at least two first through-holes are defined on a same face of the converter housing.

6. The DC-AC converter according to claim 1, further comprising a front panel and an output socket, wherein the front panel is fixed to the converter housing and forms a receiving space with the converter housing, and the DC-AC conversion module is received in the receiving space; and
wherein a fourth through-hole is defined on the front panel, and the output socket passes through the fourth through-hole to extend from the receiving space to outside of the converter housing.

7. The DC-AC converter according to claim 6, further comprising a fan and a circuit board, wherein the fan is received in the receiving space and fixed to the front panel, and the circuit board is received in the receiving space and electrically connected to the fan; and
a heat emission hole is defined on a side wall of the converter housing adjacent to a side wall of the converter housing at which the electrical connector is arranged.

8. The DC-AC converter according to claim 7, further comprising a fan bracket received in the receiving space and fixed to the front panel, wherein the fan is fixed on the fan bracket.

9. An alternating current (AC) output device, comprising:
a battery module; and
a direct current to alternating current (DC-AC) converter, comprising:
a converter housing;
an electrical connector, arranged on the converter housing and configured to be connected with the battery module;
a DC-AC conversion module, arranged in the converter housing and configured to convert a direct current output from the battery module to an alternating current; and
a detachable connection structure, arranged on the converter housing and configured to be detachably connected with the battery module;
wherein the battery module is detachably connected to the DC-AC converter, and the battery module is electrically connected to the DC-AC conversion module.

10. The AC output device according to claim 9, wherein a groove is defined on the battery module, and the groove is detachably connected with the detachable connection structure of the DC-AC converter.

11. The AC output device according to claim 9, comprising at least two detachable connection structures arranged on the converter housing, wherein the at least two detachable connection structures are spaced from each other; and
at least two first through-holes are defined on the converter housing, wherein the at least two detachable connection structures and the at least two first through-holes are in one-to-one correspondence, and a respective detachable connection structure passes through a corresponding first through-hole.

12. The AC output device according to claim 11, wherein each of the at least two detachable connection structures comprises a clasp member configured to fasten with a groove defined on the battery module.

13. The AC output device according to claim 12, wherein the clasp member comprises a resilient part having two ends opposite to each other, a hook, and a controlling button, wherein one end of the resilient part is fixed to an inner wall of the converter housing, the other end of the resilient part is connected to the hook, and the hook passes through a corresponding first through-hole to extend from inside to outside of the converter housing;
a second through-hole is defined on the converter housing, wherein the controlling button is inserted in the second through-hole and connected with the hook, the at least two first through-holes are defined on a first face of the converter housing, and the second through-hole is defined on a second face of the converter housing different from the first face.

14. The AC output device according to claim 11, wherein a third through-hole is defined on the converter housing, the electrical connector passes through the third through-hole to extend to outside of the converter housing, and the third through-hole and the at least two first through-holes are defined on a same face of the converter housing.

15. The AC output device according to claim 9, further comprising a front panel and an output socket, wherein the front panel is fixed to the converter housing and forms a receiving space with the converter housing, and the DC-AC conversion module is received in the receiving space; and
wherein a fourth through-hole is defined on the front panel, and the output socket passes through the fourth through-hole to extend from the receiving space to outside of the converter housing.

16. The AC output device according to claim 15, further comprising a fan and a circuit board, wherein the fan is received in the receiving space and fixed to the front panel, and the circuit board is received in the receiving space and electrically connected to the fan; and
a heat emission hole is defined on a side wall of the converter housing adjacent to a side wall of the converter housing at which the electrical connector is arranged.

17. The AC output device according to claim 16, further comprising a fan bracket received in the receiving space and fixed to the front panel, wherein the fan is fixed on the fan bracket.
